(19) United States
(12) Patent Application Publication
(10) Pub. No.: US 2010/0176483 A1
(43) Pub. Date: Jul. 15, 2010

(54) FUSE ELEMENT AND SEMICONDUCTOR INTEGRATED CIRCUIT WITH THE SAME

(75) Inventor: Manabu IGUCHI, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (US)

(21) Appl. No.: 12/683,751

(22) Filed: Jan. 7, 2010

(30) Foreign Application Priority Data
Jan. 9, 2009 (JP) 2009-3614

(51) Int. Cl. H01L 23/525

(52) U.S. Cl. 257/529; 257/734; 257/E23.149

(57) ABSTRACT

A fuse element according to the present invention and a semiconductor integrated circuit with the fuse element include interconnects and a via connected to a region for connecting the interconnects. A first angle between a first side surface of the via and the connect region is smaller than a second angle between a second side surface opposite the first side surface and the connect region.

This application is based upon and claims the benefit of priority from Japanese Patent Application No. 2009-003614, the disclosure of which is incorporated herein in its entirety by reference.

### BACKGROUND OF THE INVENTION

The present invention relates to semiconductor integrated circuits, and more particularly to a semiconductor integrated circuit with a fuse element.

There is a technique by which, in a semiconductor integrated circuit with a fuse, a faulty element of the semiconductor integrated circuit is separated by cutting the fuse and replaced with a normal element (for example, Japanese Patent Laid-Open No. 2001-177093). In recent years, with the increased degree of integration and the enlarged size of semiconductor integrated circuits, the number of fuses to be mounted has increased and thus the circuit area occupied by the fuses has increased.

In order to reduce the area used by fuses, a technique is known by which, in a multilayered-interconnect semiconductor integrated circuit, a via electrically connecting interconnects of vertically stacked layers is used as an electric fuse. In the semiconductor integrated circuit with the electric fuse, a faulty element is electrically replaced with a normal element by cutting the electric fuse.

Japanese Patent Laid-Open No. 2001-24063 discloses a technique for a vertically arranged fuse structure for a semiconductor device.

Japanese Patent Laid-Open No. 6-5707 discloses a fuse element which is constructed by electrically connecting, via a small-area contact hole, a first metal interconnect layer and a second metal interconnect layer formed on a semiconductor substrate.

Japanese Patent Laid-Open No. 2007-305693 discloses a technique by which: in a state before cutting an electric fuse element, the electric fuse element includes a first interconnect, a via connected to the first interconnect and a second interconnect connected to the via, each part being formed in different layers; and in a state after cutting the electric fuse, the conductive material constituting the electric fuse flows out from the second interconnect, whereby a flowing out region is formed and also a void is formed between the first interconnect and the via, or in the via.

However, the present inventor has found the following problem.

That is, in the technique using a via arranged between the interconnects of stacked layers as an electric fuse, when the electric fuse is properly broken, a faulty part can be separated from the circuit; but after cutting of the electric fuse, reattachment or the like may be made again, resulting in unsatisfactory separation by the electric fuse.

For example, after fusing of the via constituting the electric fuse, when the fused metal unexpectedly comes into contact with another interconnect, it is found that the separation by the electric fuse has become unsatisfactory.

### SUMMARY

According to the present invention, there is provided a semiconductor integrated circuit comprising a fuse element which includes:

a first interconnect;

a via formed on the first interconnect and connected to the first interconnect;

a connect region through which the first interconnect and the via are connected; and

a second interconnect formed on the via and connected to the via,

wherein the via includes:

a first side surface formed above the connect region; and

a second side surface opposite the first side surface, and

wherein a first angle between the first side surface and the connect region is smaller than a second angle between the second side surface and the connect region.

In the semiconductor integrated circuit having the above structure, it is possible to suppress occurrence of the problem that, when the electric fuse is electrically broken, the separation is unsatisfactory.

### BRIEF DESCRIPTION OF THE DRAWINGS

The above and other objects, advantages and features of the present invention will be more apparent from the following description taken in conjunction with the accompanying drawings, in which:

FIG. 1 is a plan view illustrating the configuration of a fuse element 1 according to the present embodiment;

FIG. 2 is a cross-sectional view illustrating the configuration of the fuse element 1 according to the present embodiment;

FIGS. 3A and 3B are cross-sectional views illustrating the operation of the fuse element 1 according to the present embodiment;

FIG. 4 is a cross-sectional view illustrating a first process for fabricating the fuse element 1 according to the present embodiment;

FIG. 5 is a cross-sectional view illustrating a second process for fabricating the fuse element 1 according to the present embodiment;

FIG. 6 is a cross-sectional view illustrating a third process for fabricating the fuse element 1 according to the present embodiment;

FIG. 7 is a cross-sectional view illustrating a fourth process for fabricating the fuse element 1 according to the present embodiment;

FIG. 8 is a cross-sectional view illustrating a fifth process for fabricating the fuse element 1 according to the present embodiment;

FIG. 9 is a cross-sectional view illustrating a sixth process for fabricating the fuse element 1 according to the present embodiment;

FIGS. 10A and 10B are cross-sectional views illustrating a process performed when a displacement occurs in a second resist 25 in the method of fabricating the fuse element 1 according to the present embodiment;

FIGS. 10C and 10D are cross-sectional views illustrating a process performed when a displacement occurs in the second resist 25 in the method of fabricating the fuse element 1 according to the present embodiment;

FIGS. 11A and 11B are cross-sectional views illustrating another process performed when a displacement occurs in the second resist 25 in the method of fabricating the fuse element 1 according to the present embodiment;

FIGS. 11C and 11D are cross-sectional views illustrating another process performed when a displacement occurs in the second resist 25 in the method of fabricating the fuse element 1 according to the present embodiment; and

FIGS. 12A and 12B are cross-sectional views illustrating the configuration of an electric fuse having a structure different form the fuse element 1 according to the present embodiment.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be described with reference to the drawings. In the drawings for describing the embodiments, as a rule, the same reference numeral is applied to the same member and a repeated explanation thereof is omitted.

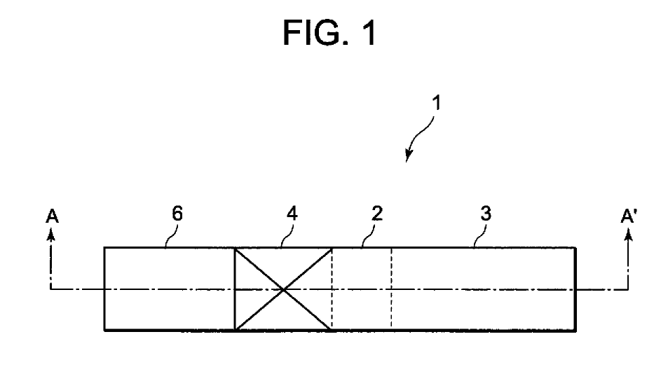

FIG. 1 is a plan view illustrating the configuration of a fuse element 1 according to the present embodiment.

A transistor (not illustrated) composed of a gate, diffusion layer, element separation and the like is constructed on a semiconductor substrate (not illustrated); and a fuse element 1 is constructed in multiple interconnect layers formed on these parts.

The fuse element 1 includes a first interconnect layer 2, a second interconnect layer 3 and a via 4. The first interconnect layer 2 and the second interconnect layer 3 are arranged in different interconnect layers. Further, a second interlayer insulating film 6 is arranged between the first interconnect layer 2 and the second interconnect layer 3. The via 4 is arranged to extend through the second interlayer insulating film 6. Further, a third interlayer insulating film 8 (not illustrated in FIG. 1) is arranged on the second interconnect layer 3.

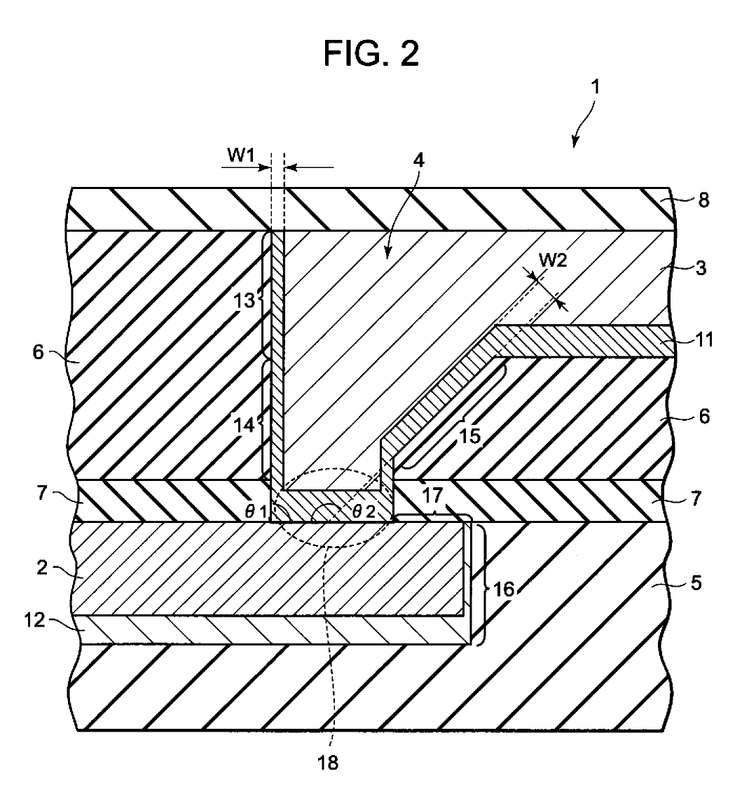

FIG. 2 is a cross-sectional view illustrating the configuration of the fuse element 1 according to the present embodiment. The cross-sectional view of FIG. 2 illustrates the cross section along the line A-A′ illustrated in FIG. 1. The fuse element 1 is, as described above, constructed correspondingly to the multiple interconnect layers. Referring to FIG. 2, the fuse element 1 includes the first interconnect layer 2, the second interconnect layer 3, the via 4, a first interlayer insulating film 5, the second interlayer insulating film 6, a stopper film 7, the third interlayer insulating film 8, a first barrier metal 11 and a second barrier metal 12.

The first interconnect layer 2 and the second interconnect layer 3 are made, for example, of copper and connected through the via 4. In a connect region 18, the via 4 is connected to the first interconnect layer 2. The second barrier metal 12 is arranged on the side surface and lower surface of the first interconnect layer 2. The first interconnect layer 2 has a first interconnect end 16. The first interconnect layer 2 is formed to include a first interconnect upper surface 17 between the connect region 18 and the first interconnect end 16.

The first interlayer insulating film 5 formed around the first interconnect layer 2 electrically insulates the first interconnect layer 2 from interconnects below the first interconnect layer 2. The stopper film 7 is arranged on the first interlayer insulating film 5. The second interlayer insulating film 6 is arranged on the stopper film 7 and electrically insulates the first interconnect layer 2 from the second interconnect layer 3. The third interlayer insulating film 8 is arranged on the second interconnect layer 3. The third interlayer insulating film 8 electrically insulates the second interconnect layer 3 from interconnects above the second interconnect layer 3. The first barrier metal 11 is arranged between the second interconnect layer 3 and the second interlayer insulating film 6.

The via 4 is formed in a manner extending without a break from the second interconnect layer 3 so as to be connected to the second interconnect layer 3. The via 4 has a via first side surface 14 and a via second side surface 15. The second interconnect layer 3 has a second interconnect end 13, and the via first side surface 14 is formed in a manner extending without a break from the second interconnect end 13. In the connect region 18, the via 4 is connected via the first barrier metal 11 to the first interconnect layer 2. The interface between the first barrier metal 11 and the first interconnect layer 2 is formed substantially parallel to an upper surface of the first interconnect layer 2.

The surface including the via first side surface 14 of the via 4 is, as illustrated in FIG. 2, formed to tilt by first angle θ1 relative to the above interface; and the surface including the via second side surface 15 of the via 4 is formed to tilt by second angle θ2 relative to the above interface.

Here, in the via 4 of the fuse element 1 according to the present embodiment, second angle θ2 is greater than first angle θ1.

Accordingly, when voltage is applied between the first interconnect layer 2 and the second interconnect layer 3 of the fuse 1 to fuse the via 4, the metal flows out more readily to the first side surface 14 than to the second side surface 15. The reason for this is that the mechanical strength of the second interlayer insulating film 6 is smaller than that of the material constituting the stopper film 7, the first interconnect layer, the second interconnect layer and the like, and when there occurs, during the fusing, inner pressure in a direction normal to the via side surface and in an outward direction from the via, regarding the spreading path of this pressure, priority is given to the direction normal to the via first side surface 14 in which the second interlayer insulating film 6 with small mechanical strength occupies a greater area.

Further, the film thickness (hereinafter referred to as “barrier metal second film thickness W2”) of the first barrier metal 11 of the via second side surface 15 in the fuse element 1 according to the present embodiment is greater than the film thickness (hereinafter referred to as “barrier metal first film thickness W1”) of the first barrier metal 11 of the via first side surface 14 (or the second interconnect end 13). When the first barrier metal 11 surrounding the via 4 includes a part of a smaller film thickness, the metal fused during cutting of the fuse element 1 flows out more readily to that part. In the fuse element 1 according to the present embodiment, the film thickness of the first barrier metal 11 is controlled by setting first angle θ1 and second angle θ2 to different angles, whereby a part to which the metal flows out more readily is specified.

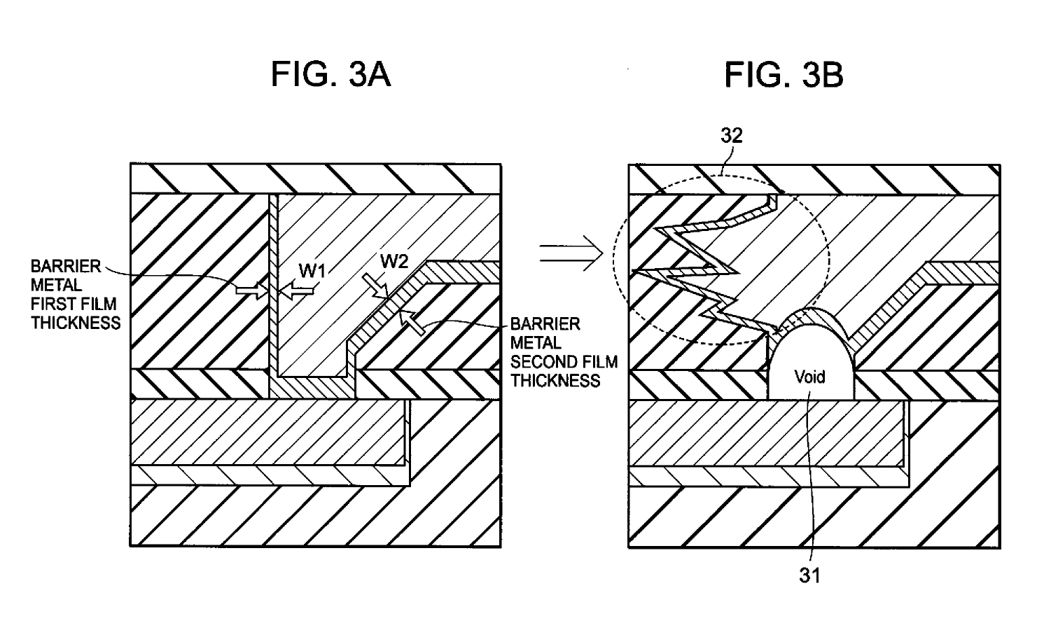

FIGS. 3A and 3B are cross-sectional views illustrating the operation of the fuse element 1 according to the present embodiment; FIG. 3A illustrates the fuse element 1 in a state before cutting the fuse element 1; and FIG. 3B illustrates the fuse element 1 in a state after cutting the fuse element 1. In the fuse element 1 according to the present embodiment, as illustrated in FIGS. 3A and 3B, when the fuse element 1 is broken, the metal can be flown out to the second interlayer insulating film 6 in the side of the via first side surface 14 (or the second interconnect end 13).

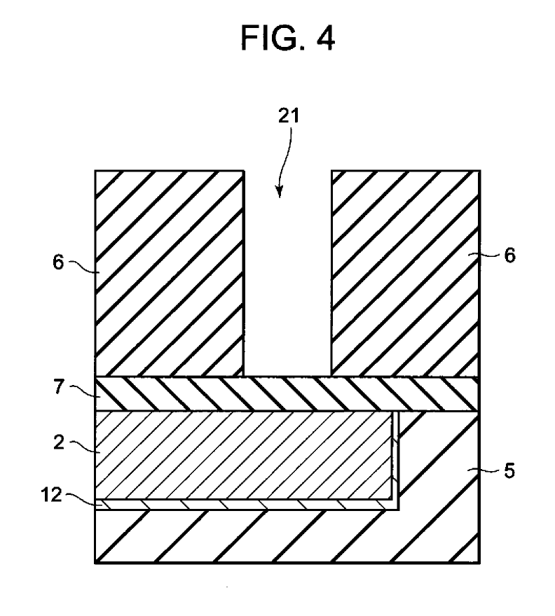

The method of fabricating the fuse element 1 according to the present embodiment will be described below with reference to the drawings. FIG. 4A is a cross-sectional view illustrating a first process for fabricating the fuse element 1 according to the present embodiment. In the cross-sectional view illustrated in FIG. 4, an illustration of interconnects and circuit parts below the first interlayer insulating film 5 is omitted. In the first process, after forming of circuit patterns and the like, the first interlayer insulating film 5 is formed on these parts. Thereafter, a recess corresponding to the interconnect pattern of the first interconnect layer 2 is formed in the first interlayer insulating film 5. The second barrier metal 12 and the first interconnect layer 2 are formed in the formed recess and thereafter the stopper film 7 and the second interlayer insulating film 6 are formed thereon. Then, an opening 21 for forming the via 4 is arranged in the second interlayer insulating film 6.

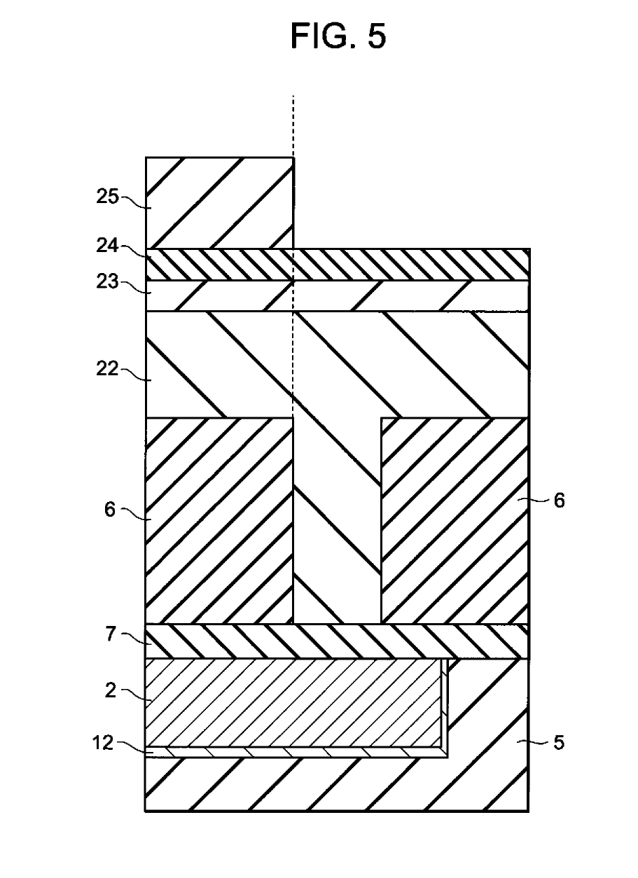

FIG. 5 is a cross-sectional view illustrating a second process for fabricating the fuse element 1 according to the present embodiment. In the second process, a first resist 22 to fill the opening 21 is formed. In this case, the surface of the second interlayer insulating film 6 is covered by the first resist 22. Thereafter, a buffer film 23 and an ARC (Anti Reflective Coating) film 24 are formed on the first resist 22. Then, a second resist 25 corresponding to the interconnect pattern of the second interconnect layer 3 is formed on the ARC (Anti Reflective Coating) film 24.

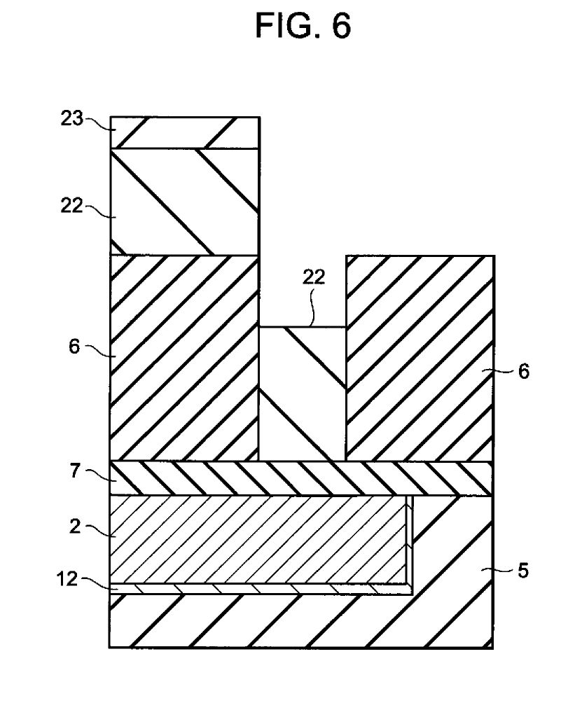

FIG. 6 is a cross-sectional view illustrating a third process for fabricating the fuse element 1 according to the present embodiment. In the third process, the ARC (Anti Reflective Coating) film 24, the buffer film 23 and first resist 22 are removed by using the second resist 25 as a mask. Thereafter, the second resist 25 and the ARC (Anti Reflective Coating) film 24 are removed, whereby the buffer film 23 is constructed which has a pattern for forming the second interconnect layer 3.

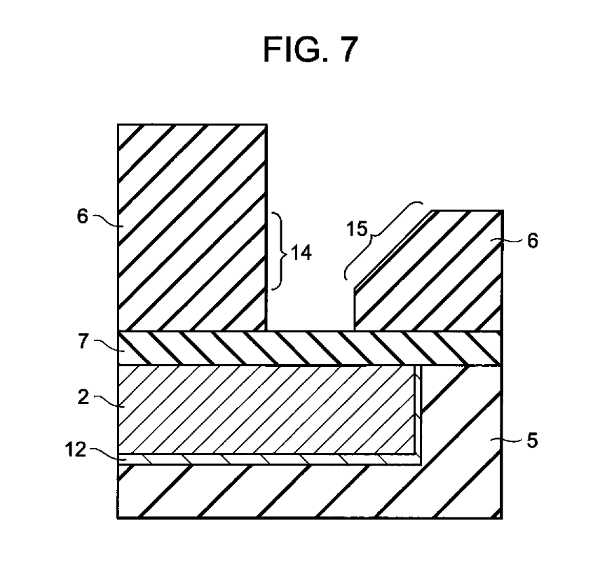

FIG. 7 is a cross-sectional view illustrating a fourth process for fabricating the fuse element 1 according to the present embodiment. In the fourth process, a recess for forming the second interconnect layer 3 is arranged in the second interlayer insulating film 6 by using the buffer film 23 as a mask. Thereafter, the buffer film 23 and the first resist 22 are removed to expose the covered surface of the second interlayer insulating film 6 and the surface of the stopper film 7. In the fourth process, as illustrated in FIG. 7, when the recess for forming the second interconnect layer 3 is formed, a side surface of the second interlayer insulating film 6 not covered by the buffer film 23 and the first resist 22 is chipped off to a greater degree than a covered side surface thereof. Thus, the part corresponding to the via first side surface 14 has a taper angle different from that of the part corresponding to the via second side surface 15.

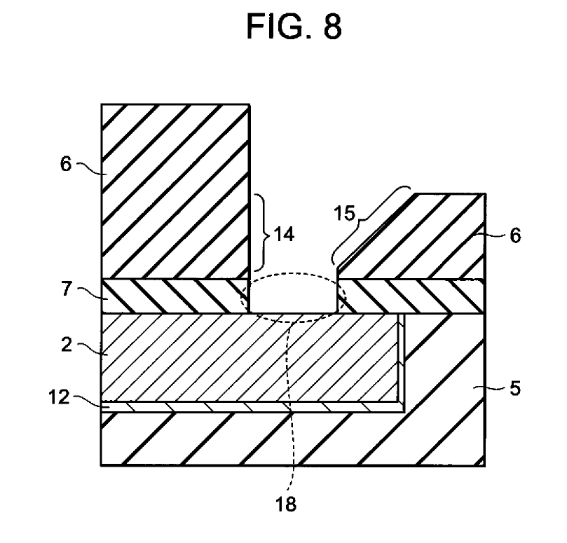

FIG. 8 is a cross-sectional view illustrating a fifth process for fabricating the fuse element 1 according to the present embodiment. In the fifth process, the exposed part of the stopper film 7 is selectively removed. As a result, that surface of the first interconnect layer 2 corresponding to the connect region 18 is exposed.

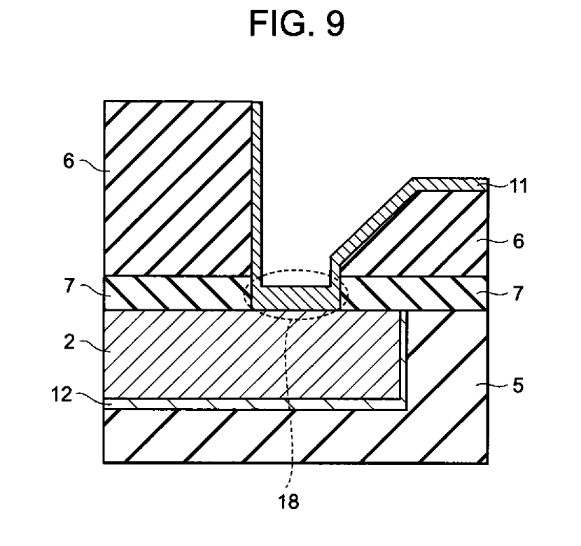

FIG. 9 is a cross-sectional view illustrating a sixth process for fabricating the fuse element 1 according to the present embodiment. In the sixth process, the first barrier metal 11 is formed so that the exposed surface of the second interlayer insulating film 6 and the surface of the first interconnect layer 2 corresponding to the connect region 18 are covered. In this case, the film thickness of the first barrier metal 11 is smaller in the side surface of the second interlayer insulating film 6 having a sharper tilt relative to the surface of the first interconnect layer 2; and the film thickness of the first barrier metal 11 is greater in the side surface of the second interlayer insulating film 6 having a slighter tilt relative to the surface of the first interconnect layer 2.

Thereafter, the second interconnect layer 3 is formed and then the third interlayer insulating film 8 is formed thereon. When the fuse element 1 according to the present embodiment is formed by the above described fabrication method, the film thickness of the first barrier metal 11 can be controlled in the fabrication process.

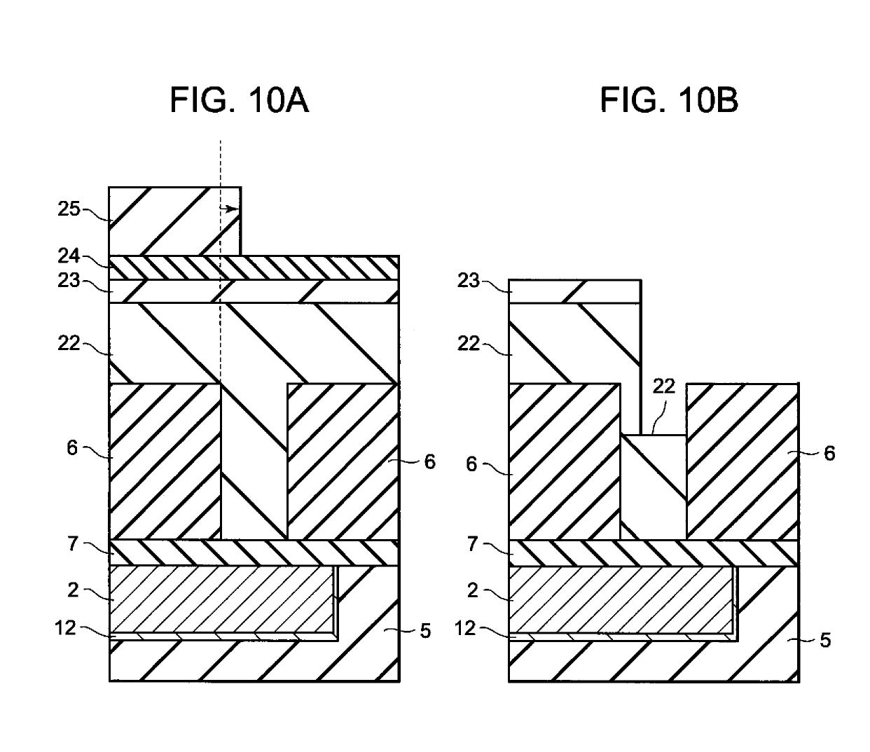

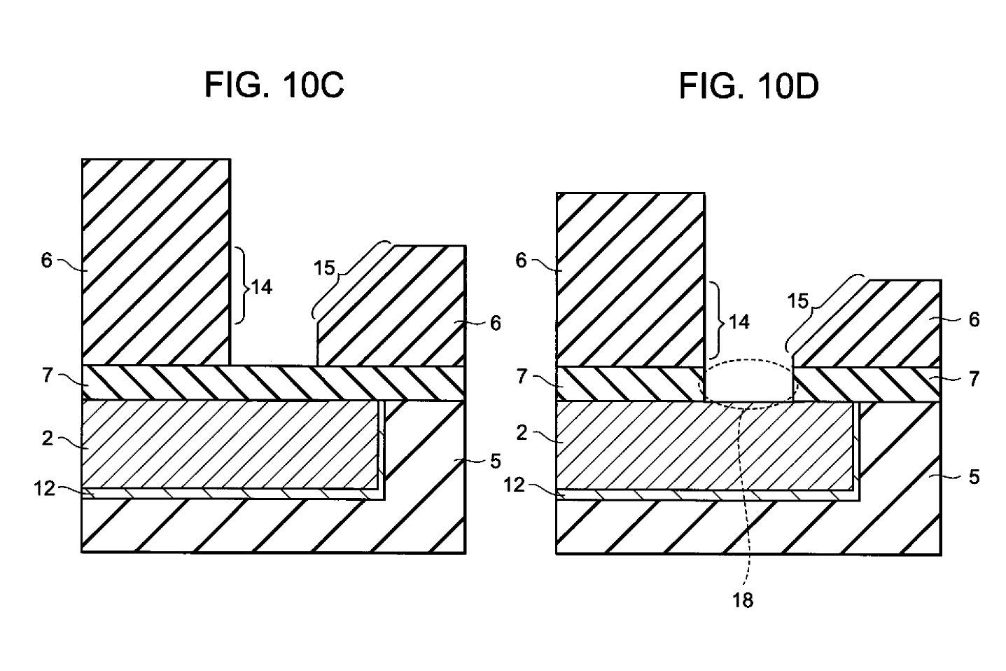

FIGS. 10A, 10B, 10C and 10D are a cross-sectional view illustrating a process performed when a displacement occurs in the second resist 25 in the method of fabricating the fuse element 1 according to the present embodiment. FIG. 10A corresponds to the second process; and FIG. 10B corresponds to the third process. FIG. 10C corresponds to the fourth process; and FIG. 10D corresponds to the fifth process.

FIGS. 10A, 10B, 10C and 10D illustrate a case in which, in the second process for fabricating the fuse element 1 according to the present embodiment, the second resist 25 is formed to overlap the side surface of the opening 21. In this case, in the fuse element 1 according to the present embodiment, similarly to the above described fabrication process, an opening can be formed which has a taper angle such that the part corresponding to the via first side surface 14 and the part corresponding to the via second side surface 15 have different taper angles.

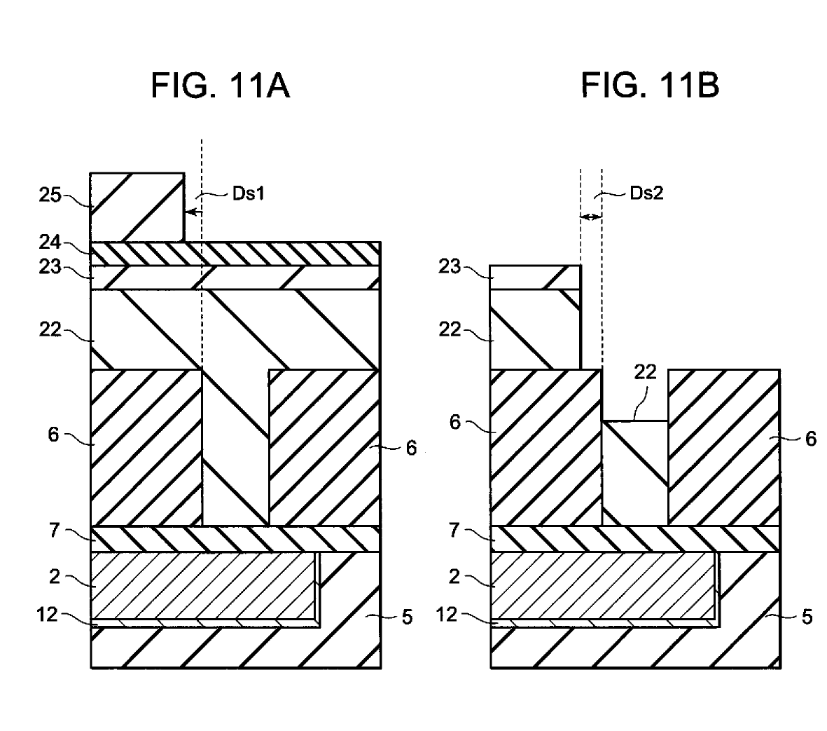

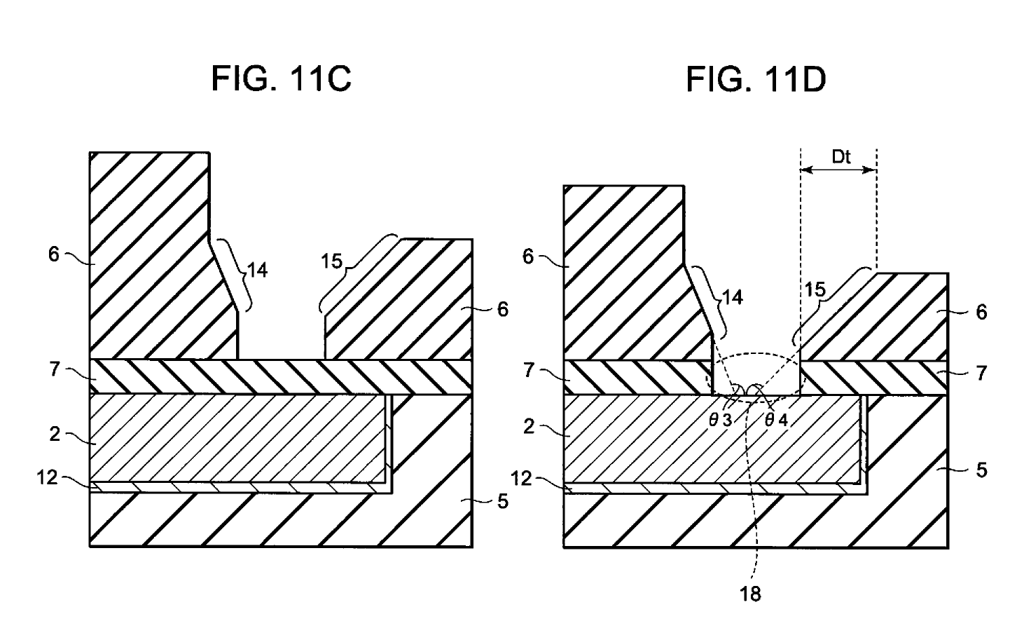

FIGS. 11A, 11B, 11C and 11D are a cross-sectional view illustrating another process performed when a displacement occurs in the second resist 25 in the method of fabricating the fuse element 1 according to the present embodiment. FIG. 11A corresponds to the second process; and FIG. 11B corresponds to the third process. FIG. 11C corresponds to the fourth process; and FIG. 11D corresponds to the fifth process.

FIGS. 11A, 11B, 11C and 11D illustrate a case in which, in the second process for fabricating the fuse element 1 according to the present embodiment, the second resist 25 is formed distant from the side surface of the opening 21. In this case, in the fuse element 1 according to the present embodiment, similarly to the above described fabrication process, the part corresponding to the via first side surface 14 is tilted. As illustrated in FIG. 11D, an opening is formed which has a taper angle such that the relationship between third angle θ3 corresponding to the tilt of the via first side surface 14 and fourth angle θ4 corresponding to the tilt of the via second side surface 15 is as follows:

θ3<θ4

Thus, in the subsequent process, when the first barrier metal 11 is formed, the film thickness of the first barrier metal 11 is smaller in the side surface of the second interlayer insulating film 6 tilted at third angle θ3; and the film thickness of the first barrier metal 11 is greater in the side surface of the second interlayer insulating film 6 tilted at fourth angle θ4.

Preferably, control is given so that horizontal distance Ds1 between the side surface of the second resist 25 and the via side surface (the wave line of FIG. 11A) of FIG. 11A, or horizontal distance Ds2 between the side surface of the first resist 22 and the buffer film 23 above the second interlayer insulating film 6 and the via side surface of FIG. 11B is smaller than distance Dt of the cross position of the plane containing the bottom of the recess for forming the second interconnect layer and the second side surface 15 from the normal line of the connect region 18 passing through the end of the connect region 18 in the side of the second side surface 15 of FIG. 11D. With this configuration, the difference between third angle θ3 and fourth angle θ4 can be enlarged.

### Comparative Example

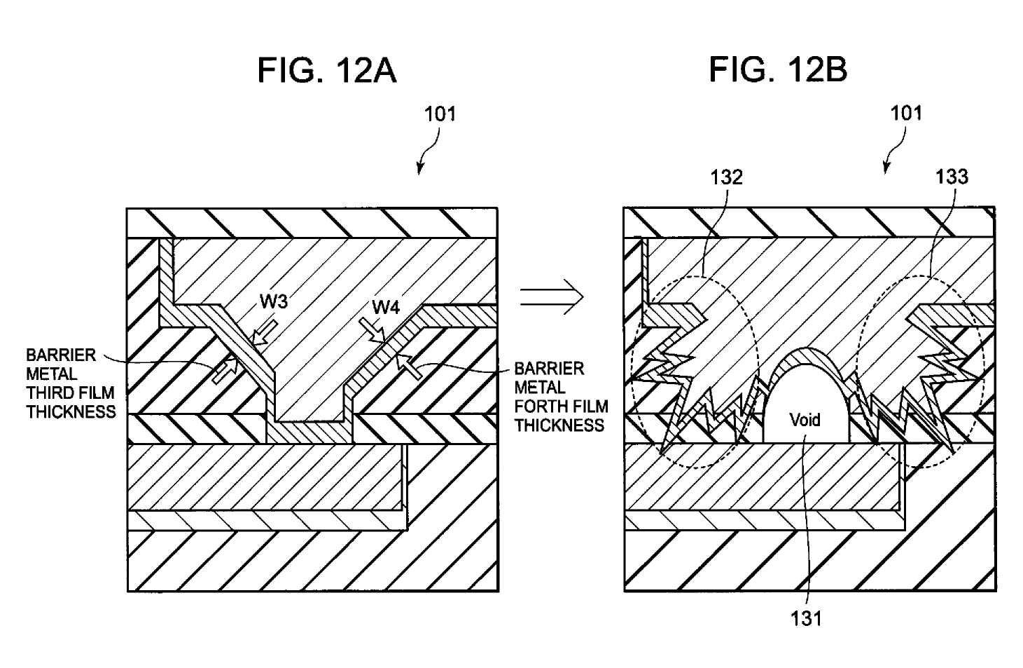

A comparative example will be described below to facilitate understanding of the present invention. FIGS. 12A and 12B are a cross-sectional view illustrating the configuration of an electric fuse having a structure different form the fuse element 1 according to the present embodiment. FIG. 12A illustrates the configuration of an electric fuse 101 in a state before cutting the electric fuse. FIG. 12B illustrates the configuration of the electric fuse 101 in a state after cutting the electric fuse. The side surface of the via of the electric fuse 101 in the side of the end face thereof has, as illustrated in FIG. 12A, substantially the same angle as that in the side of the interconnect layer thereof. Thus, barrier metal third film thickness W3 and barrier metal fourth film thickness W4 of the barrier metal are substantially equal.

When the electric fuse 101 having a structure different from the fuse element 1 according to the present embodiment is broken, a void 131 is formed, as illustrated in FIG. 12B. As described above, barrier metal third film thickness W3 and barrier metal fourth film thickness W4 are substantially equal, and substantially the same angle is given in these two parts. Consequently, the fused metal may flow out in a direction of the first interconnect layer 2 in a metal flowing out region 132 or 133. As a result, the second interconnect layer 3 or the first barrier metal 11 may come into contact with the first interconnect layer 2, resulting in unsatisfactory separation.

In the above described fuse element 1 according to the present embodiment, barrier metal first film thickness W1 and barrier metal second film thickness W2 are different from each other. In this case, the thinner part (the second interconnect end 13 and the via first side surface 14) of the first barrier metal 11 has a lower mechanical strength than the thicker part (via second side surface 15). Thus, the fused metal interconnect flows out from the second interconnect end 13 and the via first side surface 14 in an extending direction of the interconnect. Accordingly, in the fuse element 1 according to the present embodiment, short circuit between the first interconnect layer 2 and the second interconnect layer 3 can be suppressed when the fuse element 1 is broken.

The present invention includes the following.

### Method A

A method of fabricating a fuse element, comprising:

forming a first interconnect on a first interlayer insulating film formed on a circuit pattern;

forming on the first interlayer insulating film and the first interconnect, a second interlayer insulating film having an opening on the first interconnect;

filling the opening with a first resist and also forming the first resist on the second interlayer insulating film;

forming a buffer film on the first resist; forming on the buffer film, a second resist corresponding to an interconnect pattern of a second interconnect layer;

forming the interconnect pattern of the second interconnect layer in the buffer film by using the second resist as a mask;

arranging in the second interlayer insulating film, a recess for forming the second interconnect layer, by using the buffer film as a mask and also chipping off to a greater degree a side surface of the opening of the second interlayer insulating film not covered by the buffer film and the first resist film than a covered side surface of the opening;

removing the buffer film having a pattern for forming the second interconnect layer and the first resist; and

forming a via and a second interconnect made of a conductive material in the opening and in the recess arranged in the second interlayer insulating film.

### Method B

The method of fabricating a fuse element according to Method A,

wherein when the recess for forming the second interconnect layer is arranged in the second interlayer insulating film by using the buffer film as a mask, the recess for forming the second interconnect layer is formed in the second interlayer insulating film so that a part of the opening corresponding to a first side surface has a taper angle different from that of a part of the opening corresponding to a second side surface.

The method of fabricating a fuse element according to Method B, further comprising forming a barrier metal in the opening and in the recess arranged in the second interlayer insulating film before forming in the opening and the recess arranged in the second interlayer insulating film, the via and the second interconnect made of a conductive material,

wherein the film thickness of the barrier metal in the sharply tilted side surface of the opening is smaller than the film thickness of the barrier metal in the slightly tilted side surface of the opening.

It is apparent that the present invention is not limited to the above embodiments, but may be modified and changed without departing from the scope and spirit of the invention.

What is claimed is:

1. A semiconductor integrated circuit comprising a fuse element which includes:
a first interconnect;
a via formed on the first interconnect and connected to the first interconnect;
a connect region through which the first interconnect and the via are connected; and
a second interconnect formed on the via and connected to the via,
wherein the via includes:
a first side surface formed above the connect region; and
a second side surface opposite the first side surface, and
wherein a first angle between the first side surface and the connect region is smaller than a second angle between the second side surface and the connect region.

2. The semiconductor integrated circuit according to claim 1,
wherein the via further includes a barrier metal formed on the first side surface and on the second side surface, and
wherein the film thickness of the barrier metal formed on the first side surface is smaller than the film thickness of the barrier metal formed on the second side surface.

3. The semiconductor integrated circuit according to claim 1,
wherein the first interconnect includes:
a first interconnect end intersecting with a plane including the connect region; and
a first interconnect upper surface disposed between the first interconnect end and the connect region.

4. The semiconductor integrated circuit according to claim 1,
wherein the second angle is greater than 90 degrees.

5. The semiconductor integrated circuit according to claim 1,
wherein the fuse element includes an interlayer insulating film between the first interconnect and the second interconnect.

6. The semiconductor integrated circuit according to claim 5,
wherein the via extends through the interlayer insulating film so that the first interconnect is connected to the second interconnect.

7. A fuse element comprising:
a first interconnect;
a via formed on the first interconnect and connected to the first interconnect;
a connect region through which the first interconnect and the via are connected; and
a second interconnect formed on the via and connected to the via,
wherein the via includes:
a first side surface formed above the connect region; and
a second side surface opposite the first side surface, and
wherein a first angle between the first side surface and the connect region is smaller than a second angle between the second side surface and the connect region.

8. The fuse element according to claim 7,
wherein the via further includes a barrier metal formed on the first side surface and the second side surface, and
wherein the film thickness of the barrier metal formed on the first side surface is smaller than the film thickness of the barrier metal formed on the second side surface.

9. The fuse element according to claim 7,
wherein the first interconnect includes:
a first interconnect end intersecting with a plane including the connect region; and
a first interconnect upper surface disposed between the first interconnect end and the connect region.

10. The fuse element according to claim 7,
wherein the second angle is greater than 90 degrees.
